(19) United States
(12) Patent Application Publication
(10) Pub. No.: US 2002/0135980 A1
(43) Pub. Date: Sep. 26, 2002

(54) High heat flux electronic cooling apparatus, devices and systems incorporating same

(75) Inventor: Kambiz Vafai, Columbus, OH (US)

Correspondence Address: STANDLEY & GILCREST LLP, 495 METRO PLACE SOUTH, SUITE 210, DUBLIN, OH, 43017, US

(73) Assignee: The Ohio State University, Columbus, OH (US)

(21) Appl. No.: 10/026,365

(22) Filed: Dec. 18, 2001

Related U.S. Application Data
(63) Continuation of application No. 09/613,657, filed on Jul. 11, 2000, now abandoned.

(51) Int. Cl. H05K 7/20

(52) U.S. Cl. 361/700; 174/15.2; 165/104.33

(57) ABSTRACT

The present invention relates to a design for high heat flux electronic cooling. The design utilizes a flat-shaped heat pipe or multi-layered micro-channel heat sink, or a combination thereof, in direct contact with the surface of microelectronics opposite the direction of the microelectronic leads. The flat-shaped heat pipe may be of any appropriate shape, such as a disk or flat plate. These heat pipes have substantial favorable advantages compared to conventional symmetrical cylindrical heat pipes. One of these advantages is the easy geometrical adaptation and higher heat removal capcabilites. In many applications, such as electronics cooling and spacecraft radiator segments, it is difficult to effectively utilize a conventional cylindrical heat pipe due to the limited heat source and sink areas. In such applications a flat shaped heat pipe may be more suitable, due to its easy geometrical adaptation and readily accessible platform for asymmetrical heating/cooling conditions.

### TECHNICAL FIELD OF THE INVENTION

The present invention is in the field of electronic cooling and temperature regulation.

### BACKGROUND OF THE INVENTION

This invention relates to heat transfer apparatus useful in electronic devices. More specifically, this invention relates to the removal of heat from microelectronics that are useful in computerized devices.

The problem of heat removal has become an important factor in the advancement of microelectronics, due to drastically increased integration density of chips in digital devices as well as an increased current-voltage handling capability of power electronic devices. The task of removing a large amount of dispersed heat from a constrained, small space is often beyond the capability of conventional cooling techniques. New methods with heat removal capabilities at least one order larger than that of conventional ones are therefore required.

It is therefore an object of the present invention to develop an improved apparatus for cooling microelectronics and the like.

Although described with respect to the fields of computers and microelectronics, it will be appreciated that similar advantages of a high performance and compact cooling scheme may obtain in other applications of the present invention. Such advantages may become apparent to one of ordinary skill in the art in light of the present disclosure or through practice of the invention.

### SUMMARY OF THE INVENTION

The present invention includes heat transfer apparatus, heat transfer devices, and heat transfer systems. The invention also includes machines or electronic devices using these aspects of the invention. The present invention may also be used to upgrade, repair or retrofit existing machines or electronic devices or instruments of these types, using methods and components known in the art.

The present invention relates to high heat flux electronic cooling. The invention utilizes a flat-shaped heat pipe or multi-layered micro-channel heat sink, or a combination thereof. As a high thermal conductor, heat pipes have been used in different applications such as energy conversion, energy storage systems, and electronic cooling. The flat plate heat pipe functions in a substantially different manner than conventional tubular heat pipes, as it involves a more complex transport mechanism. Due to its favorable thermal characteristics, a flat plate heat pipe is preferable in applications such as the cooling of high power semiconductor chips and electronic equipment. It also finds application in spacecraft radiator segments and in the thermal management of irradiation facilities.

A flat-shaped heat pipe used in accordance with the present invention may be of any appropriate shape, but preferably a disk or flat rectangular plate. Based on prior investigations of flat shaped heat pipes, these heat pipes have substantial favorable advantages compared to conventional symmetrical cylindrical heat pipes. One of these advantages is the easy geometrical adaptation. In many applications, such as electronics cooling and spacecraft radiator segments, it is difficult to effectively utilize a conventional cylindrical heat pipe due to the limited heat source and sink areas. In such applications a flat shaped heat pipe may be more suitable, due to its easy geometrical adaptation and readily accessible platform for asymmetrical heating/cooling conditions.

Another advantage of the flat shaped heat pipe is its very localized heat dissipation. For particularly short distances, the advantage of using a cylindrical heat pipe as a high conductivity thermal bus may not be as great. Another advantage of the flat shaped heat pipe is its higher heat transfer capability compared to cylindrical heat pipes. Compared to conventional cylindrical heat pipes, the flat shaped heat pipe provides much larger wick cross sectional area for condensate return. This results in a significant increase in the capillary limit of the flat shaped heat pipe. Furthermore, unlike cylindrical heat pipes, the flat shaped heat pipe of the present invention provides more than one path for condensate to return to the evaporator section. When one wick path reaches its maximum capillary pumping limit, the other wick path may not have reached its maximum capillary pumping limit and supply liquid directly to the evaporator section to prevent the evaporator from drying out. This feature would be advantageous in the case of an accidental increase in the input power.

Research results show that a flat shaped heat pipe using water as the working fluid can dissipate heat fluxes up to 300 W/cm². This number may increase after proper optimization. Another advantage of a flat shaped heat pipe is its ability to produce a surface with very small temperature gradient across it. This near-isothermal surface can be used to even out and remove hot spots, and would be useful in many applications. For example, by mounting a number of electronic components on a flat shaped heat pipe, they may be operated at virtually a common temperature due to the built-in equalization process on the surface of the flat shaped heat pipe.

Micro-channel heat sink has also been studied and tested as a high performance and compact cooling scheme in microelectronics applications. It has been shown that thermal resistance as low as 0.03° C./W is obtainable for micro-channel heat sinks, which is substantially lower than conventional channel-sized heat sinks. Design factors that have been studied include coolant selection (air and liquid coolant), inclusion of phase change (one phase and two phase), and structural optimization. One drawback of micro-channel heat sink is the relatively higher temperature rise along the micro-channels compared to that for the traditional heat sink designs. In the micro-channel heat sink the large amount of heat generated by semiconductor chips is carried away from the package by a relatively small amount of coolant, the coolant thereby exiting at a relatively high temperature.

This undesirable temperature gradient is an important consideration in the design of an electronic cooling scheme. A large temperature rise produces thermal stresses in chips and packages due to the coefficient of thermal expansion (CTE) mismatch among different materials thus undermining device reliability. Furthermore, a large temperature gradient is undesirable for the electrical performance since many electrical parameters are adversely affected by a substantial temperature rise. For instance, in power electronic devices electrical-thermal instability and thermal breakdown may occur in a high temperature region.

In one-layered micro-channel heat sink design, increasing the pressure drop across the channels can control bulk temperature rise along the channels. A larger pressure drop forces coolant to move faster through the channel. This requires a more powerful pumping power supply, generating more noise, and requiring bulkier packaging.

The present invention reduces the undesired temperature variation in the streamwise direction for the micro-channel heat sink by a design improvement, instead of increasing the pressure drop. The design in the present invention is based upon stacking multiple layers of micro-channel heat sink structures, one atop the other, with coolant flowing in different directions in each of the adjacent micro-channel layers. For such an arrangement, streamwise temperature rise for the coolant and the substrate in each layer may be compensated through conduction between the layers, resulting in a substantially reduced temperature gradient. The flow loop can be similar to the one designed for the one-layered micro-channel heat sink, except that the flow loop should branch to allow the coolant to flow from different directions, or the same direction, into each of the layers.

The present invention utilizes such a flat plate heat pipe or multi-layer microchannel heat sink in connection with heat generating electronic circuitry. While heat pipes have been used to remove heat from previous systems, shown to exhibit heat removal up to 50 W/cm², the present invention produces substantially hugher heat removal capability by placing the heat pipe and/or layered heat sink directly adjacent the top surface of the circuitry, capable of heat removal of at least 400 W/cm². Heat pipe has previously been used to cool circuitry by placing the heat pipe either between the microelectronics and the accompanying circuit board, or at the edges of a circuit board. Placing the cylindrical heat pipe between the electronics and the circuit board has the disadvantage of requiring openings to the formed in the heat pipe for the electronic leads to reach the board, or requiring the creation of an array of heat pipes running underneath the individual electronic elements. This not only requires additional formation or assembly, but also reduces the overall area of the heat pipe and limits the number and location of the channels of the heat pipe.

The present invention overcomes this problem by placing a continuous planar heat pipe in contact with the top surface of the electronics. This orientation maximizes the area for heat removal, does away with the requirement for forming a complex heat pipe or assembling a heat pipe array, and captures the heat trapped between the circuit board and the heat pipe. The results are an unexpected improvement over previous heat pipe uses. This orientation will have similar favorable results when a multi-layer microchannel heat sink is used in place of or in conjunction with the heat pipe. Such a use has never before been demonstrated. For further heat removal capabilities, the heat sink may be placed in contact with a heat pipe that is contacting the microelectronics, optionally placed on the side of the heat pipe opposite the electronics.

Therefore, the present invention includes a heat removal apparatus for use with heat generating circuitry or electronics. The apparatus utilizes a flat plate or disk-shaped heat pipe. The flat plate heat pipe comprises a top surface and a bottom surface, the surfaces being substantially parallel. The heat pipe contains substantially parallel side walls connecting the top and said bottom surfaces on two sides. Porous wicks are attached to the inner surfaces of the side walls surfaces, and at least two substantially parallel wicks run between the top and bottom surfaces. These parallel wicks are positioned so as to create vapor channels in the heat pipe. The apparatus also comprises at least one heat-generating electronic component. The heat-generating component has a top and bottom surface, and conductive leads extending from in a direction substantially opposite the top surface. The top surface of each electronic component is placed in contact with a surface of the heat pipe.

Heat pipes of the present invention may have an evaporation section on one of the exterior surfaces. The walls of a heat pipe preferably comprise a conductive metal, such as a copper plate. The wicks are preferably comprised of a porous material, such as sintered copper powder, and are preferably adapted to act as a return mechanism for any condensate generated by the heat pipe.

Another heat removal apparatus of the present invention for use with heat generating circuitry or electronics utilizes a disk-shaped flat plate heat pipe instead of a rectangular heat pipe. The heat pipe has substantially parallel circular top and bottom surfaces. Porous wicks are attached to the inner surfaces of these top and bottom surfaces. At least two channels, such as may be provided respectively by two wicks, run between the top and bottom surfaces, running from the center of the heat pipe to the edge and positioned so as to create substantially similar divergent vapor channels in the heat pipe.

Also included in the present invention is a heat removal apparatus for use with heat generating circuitry or electronics that utilizes a multi-layer microchannel heat sink. The heat sink has at least one first layer having several substantially parallel micro-channels, and at least one second layer having several substantially parallel micro-channels. Each second layer is in thermal contact with at least one first layer. The heat sink also has a device for circulating a coolant through the first and second layers such that the coolant flows through each first layer in a common direction and through each second layer in a direction opposite the flow through each first layer. The heat sink may alternatively have a plurality of layers, each layer having multiple micro-channels and being in thermal contact with at least one other layer. The device for circulating coolant would then allow coolant to flow through at least two of the layers in different directions. The apparatus may have at least one heat-generating electronic component having substantially parallel top and bottom surfaces. Conductive leads extend from the electronic component in a direction substantially opposite the top surface. The top or bottom surface of each electronic component is placed in contact with a first layer of the heat sink.

The multi-layer heat sinks of the present invention preferably further comprise a cooling device attached to the coolant-circulating device, whereby excess heat may be removed from the coolant. A heat-exchanging device may also be attached to the coolant-circulating device to remove excess heat. A coolant filter may be attached to the coolant-circulating device to remove impurities from the coolant. A coolant reservoir filter may be attached to the coolant-circulating device, whereby coolant may be stored for later use in the heat sink. The heat sinks preferably comprise a heat-conducting material such as silicon. The micro-channels preferably individually comprise dimensions less than one-sixteenth of an inch in width and height and proportional to the heat-generating surface in length.

Also included in the present invention is a heat removal apparatus combining cooling techniques of the above inventions. This invention utilizes one of the aforementioned flat heat pipes in connection with electronic circuitry (either flat plate or disk-shaped), as described above. The multi-layer microchannel heat sink of the present invention is then placed in thermal contact with the flat heat pipe, preferably adjacent to the circuitry surface. The addition of the heat sink to the heat pipe apparatus provides for greater heat removal potential.

Also included in the present invention are methods for removing heat from electronic circuitry or components. These methods involve placing a multi-layer microchannel heat sink or flat heat pipe of the present invention in contact with heat-generating electronics as described above. Other methods involve placing a heat sink in contact with a flat heat pipe, the heat pipe being placed in contact with the electronics. In this case, it is preferred that the heat sink be placed on the side of the heat pipe opposite the electronic circuitry.

### BRIEF DESCRIPTION OF THE DRAWINGS

FIG. 1 is a perspective view of a flat plate-shaped heat pipe cooling device in accordance with one embodiment of the present invention.

FIG. 2 is a perspective view of a flat disk-shaped heat pipe cooling device in accordance with one embodiment of the present invention.

FIG. 3 is a perspective schematic view of a preferred flat plate heat pipe in accordance with one embodiment of the present invention.

FIG. 4 is a side schematic view of a preferred flat plate heat pipe in accordance with one embodiment of the present invention.

FIG. 5 is a perspective schematic view of a flat heat pipe evaluation and performance system in accordance with one embodiment of the present invention.

FIG. 6 is a graphical view of the transient temperature response of a flat plate heat pipe in accordance with one embodiment of the present invention.

FIG. 7 is a graphical view of the heat transfer coefficient dependency on the input heat flux of a flat plate heat pipe in accordance with one embodiment of the present invention.

FIG. 8 is a graphical view of the effect of the input heat flux on the maximum surface temperature of a flat plate heat pipe in accordance with one embodiment of the present invention.

FIG. 9 is a graphical view of the maximum surface temperature change of a flat plate heat pipe in accordance with one embodiment of the present invention.

FIG. 10 is a graphical view of the effect of input heat flux on the maximum temperature difference of a flat plate heat pipe in accordance with one embodiment of the present invention.

FIG. 11 is a graphical view of the temperature drop across a flat plate heat pipe in accordance with one embodiment of the present invention.

FIGS. 12(a) through (d) are graphical views of the temperature distribution along the surfaces of a flat plate heat pipe in accordance with one embodiment of the present invention.

FIG. 13 is a graphical view of the surface temperature distribution at steady state of a flat plate heat pipe in accordance with one embodiment of the present invention.

FIG. 14 is a graphical view of the effect of input heat flux on the time constant of a flat plate heat pipe in accordance with one embodiment of the present invention.

FIG. 15 is (a) a schematic for a multi-layered micro-channel heat sink concept and (b) shows one embodiment of the cooling set-up for the proposed two-layered structure in accordance with one embodiment of the present invention.

FIG. 16 is an exploded perspective view of a multi-layered micro-channel heat sink in accordance with one embodiment of the present invention.

FIG. 17 is an exploded perspective view of another multi-layered micro-channel heat sink in accordance with one embodiment of the present invention.

FIG. 18 is an exploded perspective view of another multi-layered micro-channel heat sink in accordance with one embodiment of the present invention.

FIG. 19 is a front view of a feeding mechanism that may be used in conjunction with the multi-layered micro-channel heat sink of FIG. 19 in accordance with the present invention.

### DETAILED DESCRIPTION OF THE PREFERRED EMBODIMENT(S)

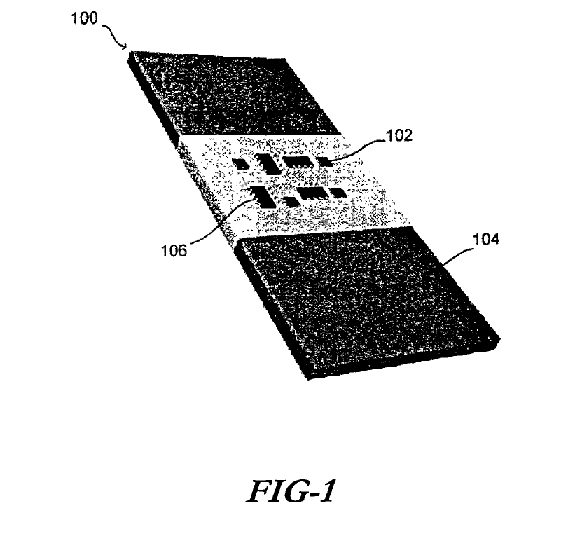

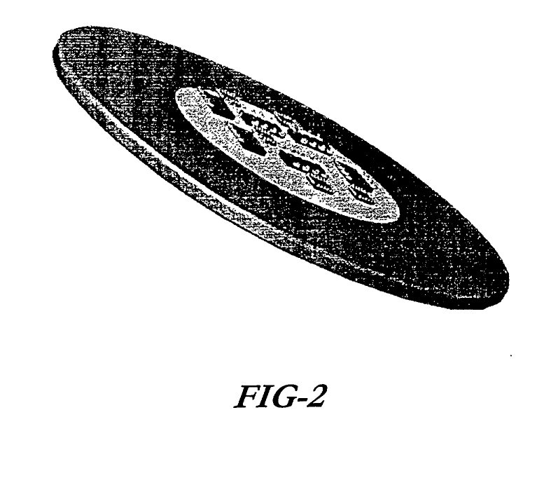

In the cooling apparatus 100 shown in FIG. 1, the microchips 102 or other heat generating bodies are preferably placed directly on the flat surface of the shaped heat pipe 104 (preferably a disk-shaped or flat plate-shaped heat pipe). Any leads 106 from the chips 102 or bodies point away from the surface of the flat shaped heat pipe 104, preferably eventually passing into an electronic device or circuit board. This arrangement may be used by itself to provide the necessary cooling, or may be used in connection with a multi-layered micro-channel heat sink to provide even greater cooling capability. In the latter case, the heat pipe and heat sink are preferably stacked upon the electronics. Alternatively, the chips or other heat-generating bodies may be placed on a flat surface of the multi-layered micro-channel heat sink, with the leads from the bodies pointing away from the heat sink. FIG. 2 shows a similar embodiment for a disk-shaped heat pipe.

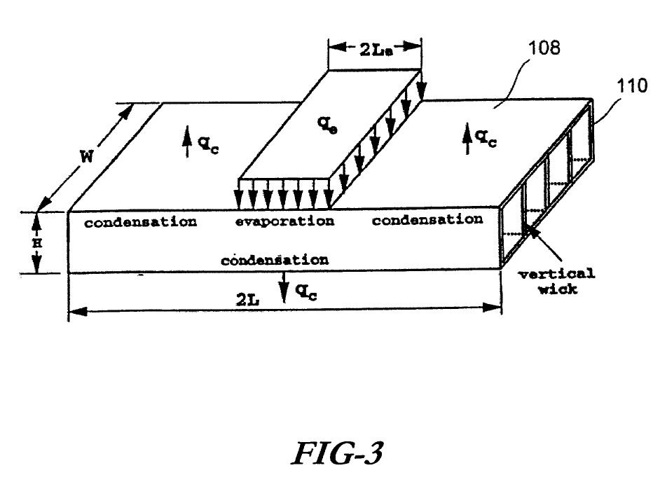

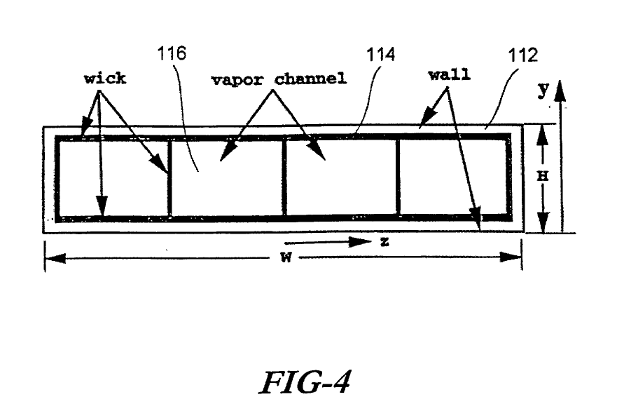

FIG. 3 is a schematic of a flat plate heat pipe 108 of one embodiment of the present invention. This heat pipe is 190.50 mm in length, 139.70 mm in width, and 34.93 mm in thickness. The heat pipe walls 110 are made of 3.175-mm thick copper plate. Attached to the inner surfaces of the heat pipe wall 112 are porous wicks 114, as shown in FIG. 4. The vertical wicks 114 provide a secondary return mechanism for the condensate. The vapor region is composed of four identical channels 116, although any appropriate number of channels may be used depending upon the application. These wicks are sintered copper powder providing a thickness of 1.651 mm. The pore radius of the wicks is 3.1×10⁻⁵ m and its porosity is 50%. The permeability of the wick is 7×10⁻¹² m².

During operation of a flat plate heat pipe, heat is transferred through the heat pipe walls by conduction. In the porous wick of the evaporator section, there is heat conduction in the porous matrix, liquid flow through the pores, and evaporation at the wick-vapor interface. Within the wick of the condenser section, there is conduction in the porous matrix, liquid flow inside the pores and condensation at the vapor-wick interface.

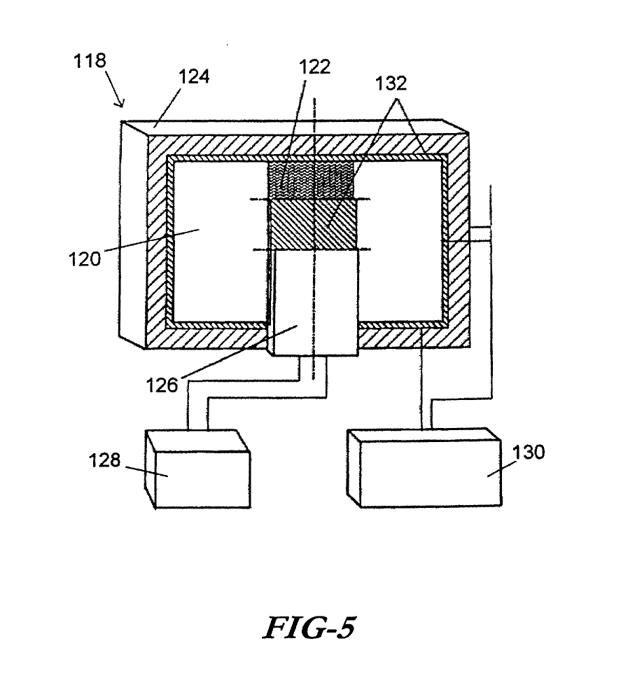

The evaporation section is preferably located on the center of one of the outside surfaces of the heat pipe. Therefore, the heat pipe can be divided into four sections, i.e., one evaporator section and three condenser sections (FIG. 3). FIG. 5 is a schematic of the experimental setup 118. Shown in FIG. 5 are the heat pipe 120, the heater 122, a Lexan frame 124, a Lexan plate 126, a power supply 128, a data acquisition system 130, and a flexible insulation material 132. During the experiment, the heat pipe 120 was positioned vertically so that the same average heat transfer coefficient existed on the three condensation surfaces. A Lexan frame of 12.7 mm thick was employed to hold the heat pipe. The function of the Lexan frame 124 was twofold: to support the heat pipe and to reduce the heat loss through the four edges of the heat pipe. Taking thermal expansion into account, the inner dimensions of the frame were made larger than that of the heat pipe's, and a 2 mm thick flexible insulation material 132 was placed between the Lexan frame 124 and the heat pipe 120. The flexible insulation material allowed the heat pipe to expand after its temperature rises. The flexible insulation material can also reduce the heat loss through surfaces other than the previously mentioned three condenser sections of the heat pipe. A support was also employed to raise the Lexan frame 124 to a certain height so as not to affect the free airflow over the outside condenser surface.

A flexible heater 122 (139.7 mm in length and 50.8 mm in width), specially designed for this experiment by the Watlow Company, was attached on the center of the top heat pipe surface. The other side of the heater was insulated (FIG. 5). Thirty E-type thermocouples were installed to measure the outside surface temperatures of the heat pipe with 15 on each surface of the heat pipe. A 6 mm×0.3 mm groove was machined in the heat pipe walls and a high conductivity cement was utilized to embed the thermocouples within the heat pipe wall. The spacing between adjacent thermocouples was 12.7 turn, except for the thermocouples at the end, which were separated 19.1 mm from each other, as shown in FIG. 5.

In order to monitor the heat loss through the insulated surfaces, thermocouples were also installed on both the inner and outer surfaces of the Lexan frame. The room temperature was also measured with two E type thermocouples. Power was fed through a power supply 128 (National Instruments) and the temperature data was collected through a data acquisition system 130. The temperature signal was monitored every second until a steady state was achieved.

Under steady state conditions, the heat transfer coefficient on the surfaces of the condenser section can be determined by

$$h = \frac{{q}_{c}}{{T}_{w a , o c} - {T}_{∞}} \qquad ( 1 )$$

where T_{wa, oc} is the average temperature of the outside surface of the wall of the condenser section and q_{c} is the output heat flux from the condenser section given by,

$${q}_{c} = \frac{Q}{{A}_{c}} \qquad ( 2 )$$

where A_{c} is the total area of the condenser section. The input heat flux in the evaporator section is

$${q}_{e} = \frac{Q}{{A}_{e}} \qquad ( 3 )$$

where Q is input power and Aₑ is the area of the evaporator section. Based on the measured average temperature of the outside surface of the evaporator wall T_{wa,oe}, T_{wa,oc}, and the input heat flux qₑ, the temperatures at the solid-liquid and liquid-vapor interfaces are obtained:

$$\begin{matrix}{T}_{w w , e} = {T}_{w a , o e} - \frac{{q}_{e} {h}_{w a}}{{k}_{w a}} & ( 4 ) \\ {T}_{w v , e} = {T}_{w w , e} - \frac{{q}_{e} {h}_{w}}{{k}_{e f f}} & ( 5 ) \\ {T}_{w w , c} = {T}_{w a , o c} + \frac{{q}_{c} {h}_{w a}}{{k}_{w a}} & ( 6 ) \\ {T}_{w v , c} = {T}_{w w , c} + \frac{{q}_{c} {h}_{w}}{{k}_{e f f}} & ( 7 )\end{matrix}$$

The temperature variation within the vapor phase is very small and thus can be neglected. The vapor temperature is then taken as

$${T}_{v} = \frac{1}{2} ( {T}_{w v , e} + {T}_{w v , c} ) \qquad ( 8 )$$

The effective thermal conductivity for the wick can be found as

$${k}_{e f f} = {k}_{1} [ \frac{{k}_{1} + {k}_{s} - ( 1 - ϵ ) ( {k}_{1} - {k}_{s} )}{{k}_{1} + {k}_{s} + ( 1 - ϵ ) ( {k}_{1} - {k}_{s} )} ] \qquad ( 9 )$$

The measured temperature uncertainty is ±0.1° C., the uncertainty of the thickness of the heat pipe wall and wick is ±0.001 mm, and the uncertainty of the heat pipe length, width, and thickness is ±0.01 mm. Based on an error analysis, the uncertainty for the input power is found to be ±1.7% and the uncertainty in measuring the heat transfer coefficient is found to be ±5.6%.

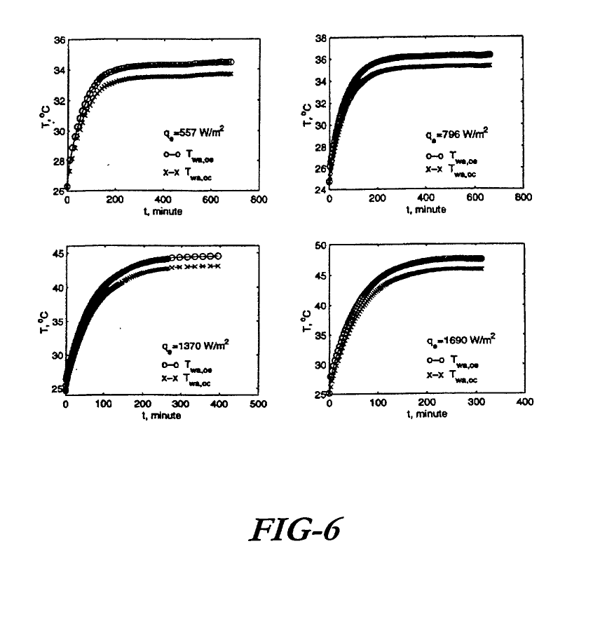

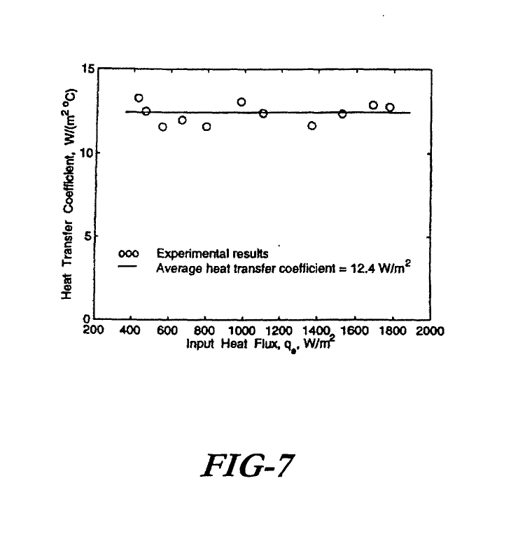

The temporal temperature distribution on the outside wall surface of the flat plate heat pipe for various input heat fluxes is shown in FIG. 6. As can be seen in FIG. 6, for higher input power, the startup time is substantially shorter. The total heat transfer coefficient on the condenser section, obtained from Eq. (1), is plotted as a function of the input heat flux in FIG. 7. As can be seen in FIG. 7, the heat transfer coefficient is relatively constant in the condenser section. The average total heat transfer coefficient under steady state conditions was found to be 12.4 W/m²° C. for surface temperatures between 30 and 49° C., with a maximum predicted relative error of ±7%.

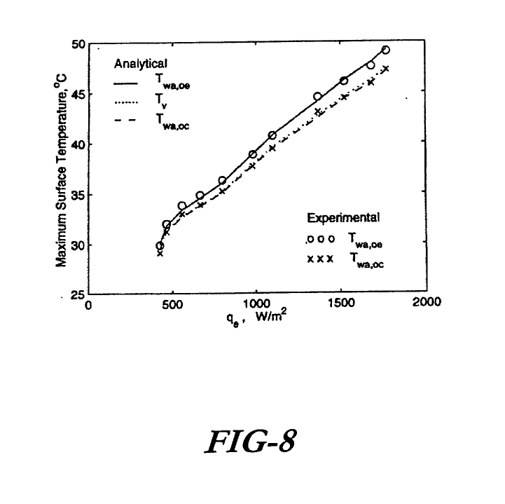

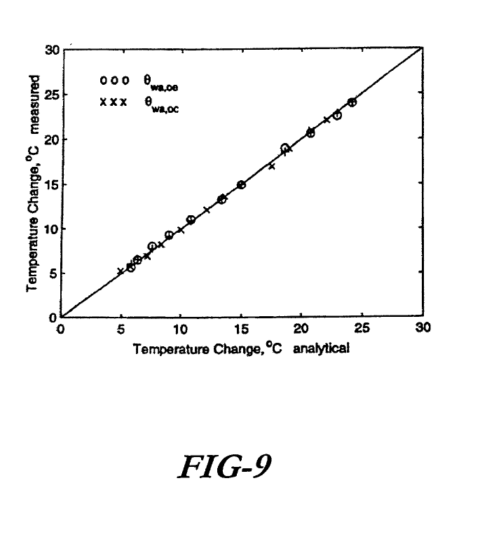

The measured maximum surface temperature is plotted against the input heat flux in FIG. 8. Based on a heat conduction model, which takes into account the room temperature, input heat flux, heat transfer coefficient and the thermophysical and geometric parameters of the heat pipe, the temperature distribution under steady-state conditions in the flat plate heat pipe can be determined analytically. The analytical results are also plotted in FIG. 8. As can be seen in FIG. 8, the maximum temperature increases with an increase in the input heat flux and the measured temperatures were found to be in good agreement with the analytical results. The measured and the analytical surface temperature rise on both the evaporator and condenser sections are plotted in FIG. 9. As can be seen, the measured temperature rise is in good agreement with the analytical results. Based on the experimental data, an empirical correlation for the maximum temperature rise in terms of the input heat flux is obtained as

θₘₐₓ=0.376+0.0133qₑ (10)

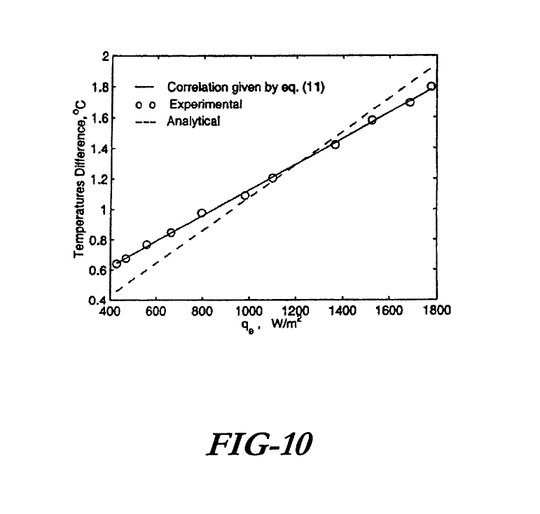

The maximum temperature difference within the heat pipe is shown in FIG. 10, which shows that the maximum temperature difference increases linearly with the input heat flux. As can be seen in FIG. 10, the maximum difference between the analytical and the experimental results is about ±0.2° C. while the uncertainty in the measured temperatures was ±0.1° C. A correlation for the maximum temperature difference within the heat pipe in terms of the input heat flux can be presented as

ΔTₘₐₓ=0.289+8.40×10⁻⁴qₑ (11)

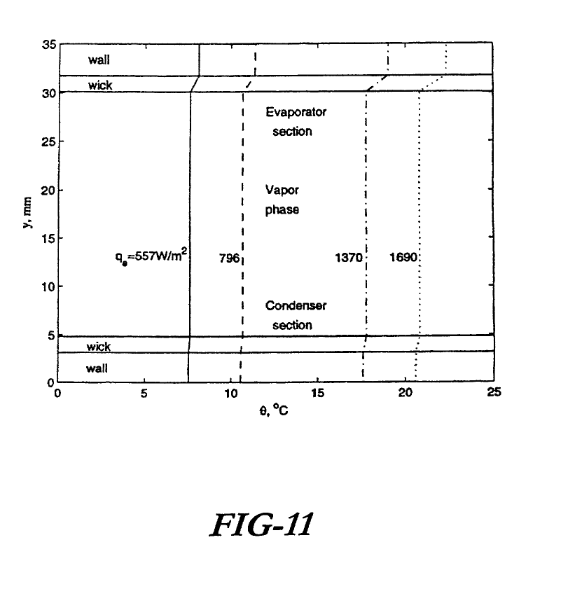

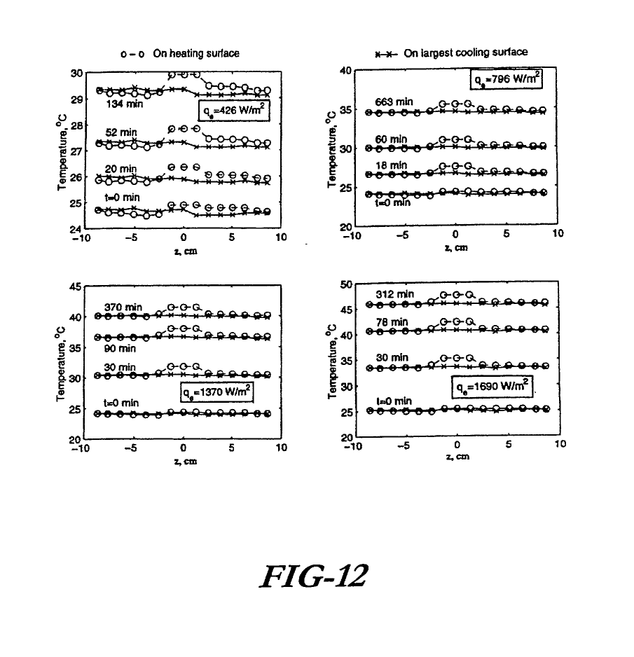

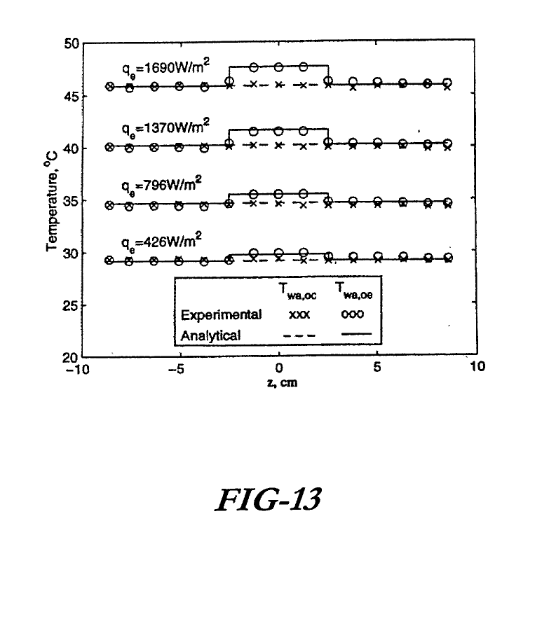

The temperature gradients across the heat pipe are shown in FIG. 11. As can be seen in FIG. 11, the temperature gradients across the heat pipe were quite small, which is one of the main characteristics of a flat plate heat pipe. FIG. 11 also shows the contribution of the heat pipe walls and wicks to the total temperature drop for different input heat fluxes. As expected for a copper or aluminum heat pipe, the temperature drop across the heat pipe wall is much smaller than that across the wicks due to the heat pipe wall's substantially larger thermal conductivity. Therefore, reducing the temperature drop across the wicks, especially in the evaporator section, is essential in improving the performance of the heat pipe. The temperature distributions along the heat pipe surfaces are plotted at different times in FIG. 12. Once again, it can be seen that the temperature was quite uniform on the largest outside surface of condenser wall. For the outside surface of the evaporator, where the input power is applied, the temperature variation is small. This is another favorable feature of a flat plate heat pipe as compared to a conventional heat pipe. This feature can be used to remove hot spots produced by arrays of heaters, or to design an efficient radiator. FIG. 13 displays the analytical and experimental temperature distributions of the heat pipe along the z-direction at steady state. As shown in FIG. 13, the analytical results agree with experimental results very well.

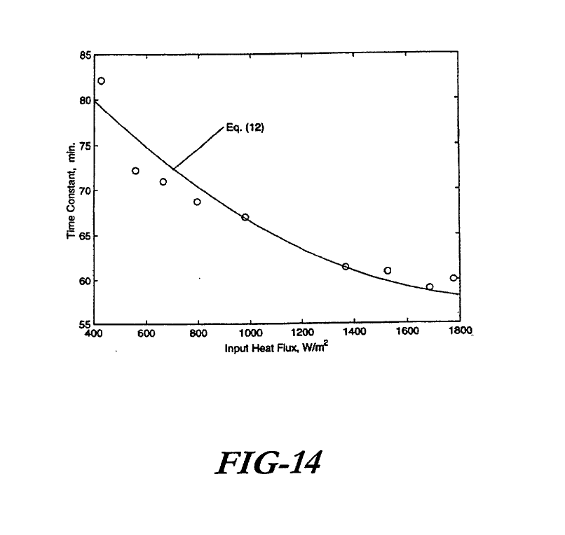

The response time to an input power is an important characteristic of a heat pipe. In this regard, the idea of a heat pipe time constant, t_{c}, was utilized in this work. This constant is defined as the time it takes for the outside surface temperature rise in the evaporator section to reach 63.2% of its maximum value. A small time constant means that the heat pipe can quickly reach its largest work capacity. The measured time constant was plotted against input heat flux in FIG. 14. As shown in FIG. 14, the time constant varies from 58 to 82 min under the present experimental conditions. Obviously, input power, the heat transfer coefficient, the temperature difference between the outside wall surface in the condenser section and the cooling fluid, and the heat capacity of the heat pipe affect the time constant. For a specified heat pipe, if the heat transfer coefficient is a constant, heat flux will have a strong effect on the time constant, as can be seen in FIG. 14. For a constant heat transfer coefficient, a larger heat flux will result in a smaller time constant. An empirical correlation for the experimental range is

t_{c}=91.4−0.0339qₑ+8.33×10⁻⁶qₑ (11)

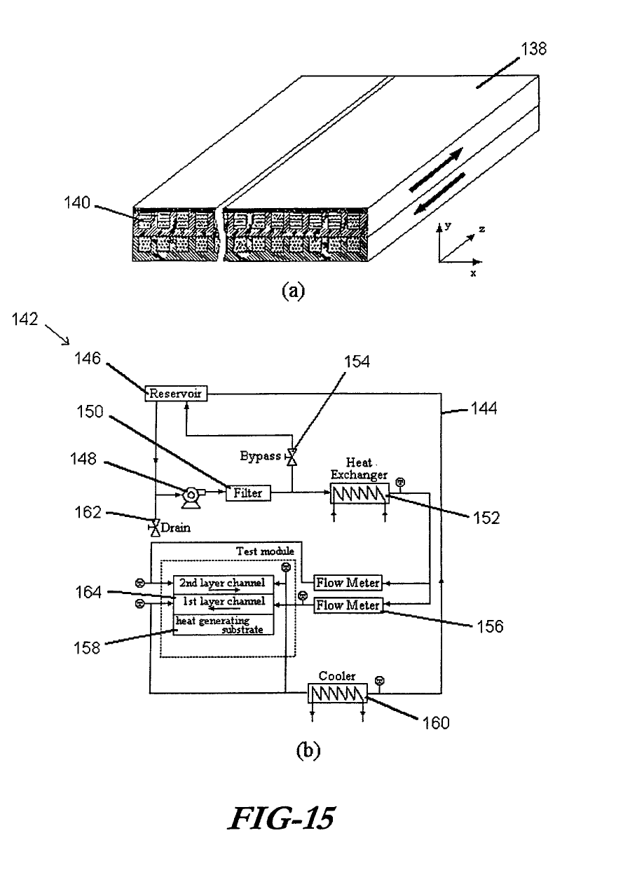

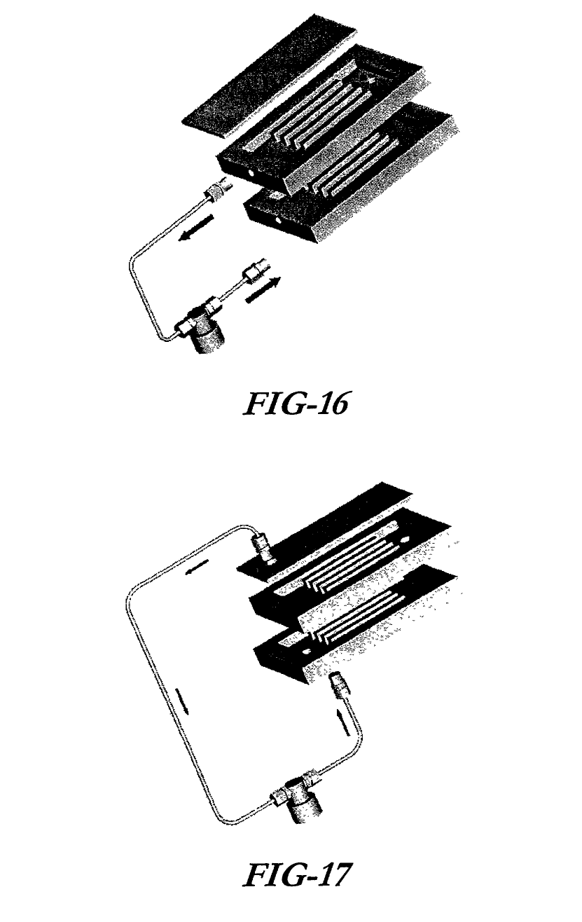

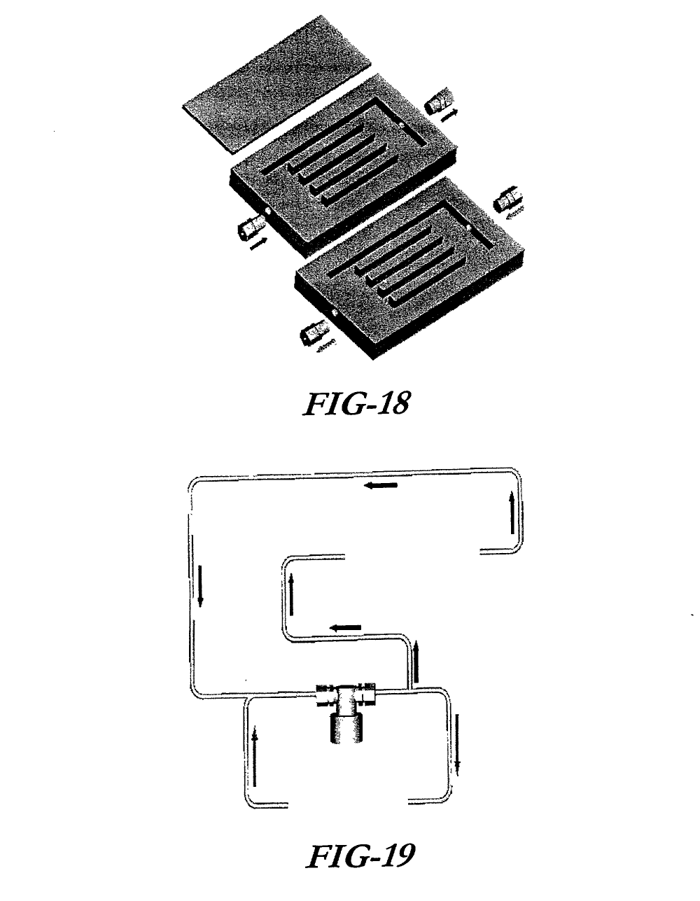

FIG. 15(a) shows a preferred multi-layer heat sink 138 comprising two layers, each layer comprised of several micro-channels 140. The heat sink 138 may be made from a conductive or semi-conductive material such as silicon. The cooling setup 142 for the preferred two-layered heat sink 164 is shown in FIG. 15(b). Coolant is drawn from a coolant reservoir 146 by a flow-transporting device 148. The coolant is passed through a coolant filter 150 to either a heat exchanger 152 or through a bypass valve back 154 to the reservoir 146. Coolant passing through the heat exchanger 152 is then bifurcated into two separate paths of flow, each path passing coolant through a separate flow meter 156. For devices with more layers, the flow may branch into multiple paths. Each flow path is then passed through one of the layers of the heat sink 164 that is in thermal contact with a heat-generating substrate 158. After passing through the micro-channels of each layer, the coolant passes through a cooler 160 and is then sent back to the coolant reservoir 146. A drain 162 is also provided to allow the changing of coolant. The ratio of coolant volume flow rate through each layer may be varied.

It should be recognized that the device is not limited to two layers, and in fact may have several stacked layers. It is preferred that no adjacent layers have coolant flowing in a common direction, so as to minimize the presence of heat gradients in the heat generating substrate. Since each channel may have coolant flowing in one of two opposing directions, and the channels in each layer do not necessarily need to be parallel to those of an adjacent layer, there may also be multiple directions of flow. For instance, in a square heat sink a given layer may have micro channels positioned opposite to or perpendicular to the direction of micro channels in an adjacent layer. Since flow may go through the micro channels in either direction, the presence of perpendicular channels provides for the possibility of 4 directions of flow through the heat sink. It should be recognized that the number of directions of flow is limited only by practicality.

In manufacturing the micro-channeled heat sink, equipment and techniques may be used that are similar to those developed and employed in the electronics semiconductor industry. One such technique that may be used to manufacture the heat sinks is silicon surface micro-machining. In a preferred example of this technique, layers of a sacrificial material such as an oxide are deposited on the surface of a silicon wafer at the location of the grooves of the heat sink. Polysilicon may be used as a structural material that is then deposited on the wafer structure, where the walls of the heat sink are located, and then etched to form the grooves and the walls. Two silicon wafers may then be bonded together using wafer-bond or other appropriate techniques. The top surface of the first layer may be covered by bonding a top layer of a polysilicon or other appropriate substrate. The wafer structure may then be cut and packaged into the final design.

### REFERENCES

1. Zhu, N., and Vafai, K. “Analytical Modeling of the Startup Characteristics of Asymmetrical Flat-Plate And Disk-Shaped Heat Pipes” International Journal of Heat and Mass Transfer, 41, 2619-2637 (1998)

2. Wang, Y., and Vafai, K. “An Experimental Investigation of the Thermal Performance of an Asymmetrical Flat Plate Heat Pipe” International Journal of Heat and Mass Transfer, 43, 2657-2668 (2000).

3. Wang, Y., and Vafai, K. “Transient Characterization of Flat Plate Heat pipes During Start-up and Shut-down Operations” International Journal of Heat and Mass Transfer, 43, 2641-2655 (2000).

4. Wang, Y., and Vafai, K. “An Experimental and Analytical Investigation of the Transient Characteristic of a Flat Plate Heat Pipe During Startup and Shutdown Operations” In Press for ASME Journal of Heat Transfer.

5. K. Vafai, and L. Zhu, Analysis of a Two-Layered Micro-Channel Heat Sink Concept in Electronic Cooling, International Journal of Heat and Mass Transfer 42 (1999) 2287-2297.

What is claimed is: Plate Heat Pipe in Conjunction with Electronic Circuitry

1. A heat removal apparatus for use with heat generating electronics, said heat removal apparatus comprising:
(a) a flat plate heat pipe, said flat plate heat pipe comprising (1) a top surface, (2) a bottom surface substantially parallel to said top surface, (3) substantially parallel side walls connecting said top surface and said bottom surface on two sides, (4) porous wicks attached to the inner surfaces of said side walls and said top and bottom surfaces, and (5) a plurality of substantially parallel wicks running between said top surface and said bottom surface, said wicks positioned so as to create vapor channels in said heat pipe; and
(b) at least one heat-generating electronic component, said heat-generating electronic component having (1) a top surface, (2) a bottom surface opposite said top surface, and (3) conductive leads extending from said electronic component in a direction substantially opposite said top surface, said top surface of each said electronic component in contact with a said surface of said heat pipe.

2. A heat removal apparatus according to claim 1 additionally comprising an evaporation section on one of said surfaces of said heat pipe.

3. A heat removal apparatus according to claim 1 wherein said walls of said heat pipe comprise a conductive metal.

4. A heat removal apparatus according to claim 3 wherein said conductive metal comprises a plate of a metal selected from the group consisting of copper and aluminum.

5. A heat removal apparatus according to claim 1 wherein said wicks are comprised of a porous material.

6. A heat removal apparatus according to claim 5 wherein said porous material is adapted to act as a return mechanism for condensate generated by said heat pipe.

7. A heat removal apparatus according to claim 5 wherein said porous material comprises sintered copper powder.
Disk Heat Pipe in Conjunction with Electronic Circuitry

8. A heat removal apparatus for use with heat generating electronics, said heat removal apparatus comprising:
(a) a flat-shaped heat pipe having flat surfaces, said flat-shaped heat pipe comprising: (1) a circular top surface, (2) a circular bottom surface substantially parallel to said circular top surface, (3) a circular envelope separating and connecting said circular top and bottom surfaces, (4) porous wicks attached to the inner surfaces of said top and bottom surfaces, and (5) a plurality of wicks running between said top surface and said bottom surface, said wicks running from the center of said heat pipe to the edge of said heat pipe and positioned so as to create substantially similar divergent vapor channels in said heat pipe; and
(b) at least one heat-generating electronic component, said heat-generating electronic component having (1) a top surface, (2) a bottom surface opposite said top surface, and (3) conductive leads extending from said electronic component in a direction substantially opposite said top surface, said top surface of each said electronic component in contact with a said surface of said heat pipe.

9. A heat removal apparatus according to claim 8 additionally comprising an evaporation section on one of said surfaces of said heat pipe.

10. A heat removal apparatus according to claim 8 wherein said walls of said heat pipe comprise a conductive metal.

11. A heat removal apparatus according to claim 10 wherein said conductive metal comprises a plate of a metal selected from the group consisting of copper and aluminum.

12. A heat removal apparatus according to claim 8 wherein said wicks are comprised of a porous material.

13. A heat removal apparatus according to claim 12 wherein said porous material is adapted to act as a return mechanism for condensate generated by said heat pipe.

14. A heat removal apparatus according to claim 12 wherein said porous material comprises sintered copper powder.
Parallel Channel Heat Sink in Conjunction with Electronic Circuitry

15. A heat removal apparatus for use with heat generating electronics, said heat removal apparatus comprising:
(a) a multi-layer microchannel heat sink, said heat sink comprising: (1) at least one first layer comprising a plurality of micro-channels; (2) at least one second layer comprising a plurality of micro-channels, each said second layer in thermal contact with at least one said first layer; and (3) a device for circulating a coolant through said first and second layers such that said coolant flows through each said first layer in a common direction and through each said second layer in a direction opposite the flow through each said first layer; and
(b) at least one heat-generating electronic component, said heat-generating electronic component having (1) a top surface, (2) a bottom surface opposite said top surface, and (3) conductive leads extending from said electronic component in a direction substantially opposite said top surface, said top surface of each said electronic component in contact with a said first layer of said heat sink.

16. A heat removal apparatus according to claim 15 further comprising a cooling device attached to said coolant circulating device whereby excess heat is removed from said coolant.

17. A heat removal apparatus according to claim 15 further comprising a heat exchanging device attached to said coolant circulating device whereby excess heat is removed from said coolant.

18. A heat removal apparatus according to claim 15 further comprising a coolant filter attached to said coolant circulating device whereby impurities may be removed from said coolant.

19. A heat removal apparatus according to claim 15 further comprising a coolant reservoir filter attached to said coolant circulating device whereby coolant can be stored for later use in said heat sink.

20. A heat removal apparatus according to claim 15 wherein said heat sink comprises a heat-conducting material selected from the group consisting of silicon.

21. A heat removal apparatus according to claim 15 wherein said micro-channels individually comprise dimensions less than one-sixteenth of an inch in width and height and proportional to said heat generating surface in length.
Generic Multi-Layer Heat Sink in Conjunction with Electronic Circuitry

22. A heat removal apparatus for use with heat generating electronics, said heat removal apparatus comprising:
(a) a multi-layer microchannel heat sink, said heat sink comprising: (1) a plurality of layers, each of said layers comprising a plurality of micro-channels, each of said layers in thermal contact with at least one other said layer; and (2) a device for circulating a coolant through said plurality of layers such that said coolant flows through at least two of said plurality of layers in different directions; and
(b) at least one heat-generating electronic component, said heat-generating electronic component having (1) a top surface, (2) a bottom surface opposite said top surface, and (3) conductive leads extending from said electronic component in a direction substantially opposite said top surface, said top surface of each said electronic component in contact with a said first layer of said heat sink.

23. A heat removal apparatus according to claim 22 further comprising a cooling device attached to said coolant circulating device whereby excess heat is removed from said coolant.

24. A heat removal apparatus according to claim 22 further comprising a heat exchanging device attached to said coolant circulating device whereby excess heat is removed from said coolant.

25. A heat removal apparatus according to claim 22 further comprising a coolant filter attached to said coolant circulating device whereby impurities may be removed from said coolant.

26. A heat removal apparatus according to claim 22 further comprising a coolant reservoir filter attached to said coolant circulating device whereby coolant can be stored for later use in said heat sink.

27. A heat removal apparatus according to claim 22 wherein said heat sink comprises a heat-conducting material selected from the group consisting of silicon.

28. A heat removal apparatus according to claim 22 wherein said micro-channels individually comprise dimensions less than one-sixteenth of an inch in width and height and proportional to said heat generating surface in length.
Electronic Device with Generic Heat Sink and Plate Heat Pipe

29. A heat removal apparatus for use with heat generating electronics, said heat removal apparatus comprising:
(a) a flat plate heat pipe, said flat plate heat pipe comprising (1) a first surface, (2) a second surface substantially parallel to said first surface, (3) substantially parallel side walls connecting said first surface and said second surface on two sides, (4) porous wicks attached to the inner surfaces of said side walls and said first and second surfaces, and (5) a plurality of substantially parallel wicks running between said first surface and said second surface, said wicks positioned so as to create vapor channels in said heat pipe;
(b) at least one heat-generating electronic component, said heat-generating electronic component having (1) a top surface, (2) a bottom surface opposite said top surface, and (3) conductive leads extending from said electronic component in a direction substantially opposite said top surface, said top surface of each said electronic component in contact with said first surface of said heat pipe; and
(c) a multi-layer microchannel heat sink, said heat sink comprising: (1) a plurality of layers, each of said layers comprising a plurality of micro-channels, each of said layers in thermal contact with at least one other said layer; and (2) a device for circulating a coolant through said plurality of layers such that said coolant flows through at least two of said plurality of layers in different directions, said heat sink placed in thermal contact with said second surface of said heat pipe.

30. A heat removal apparatus according to claim 29 additionally comprising an evaporation section on one of said surfaces of said heat pipe.

31. A heat removal apparatus according to claim 29 wherein said walls of said heat pipe comprise a conductive metal.

32. A heat removal apparatus according to claim 31 wherein said conductive metal comprises a plate of a metal selected from the group consisting of copper and aluminum.

33. A heat removal apparatus according to claim 29 wherein said wicks are comprised of a porous material.

34. A heat removal apparatus according to claim 33 wherein said porous material is adapted to act as a return mechanism for condensate generated by said heat pipe.

35. A heat removal apparatus according to claim 33 wherein said porous material comprises sintered copper powder.

36. A heat removal apparatus according to claim 29 further comprising a cooling device attached to said coolant circulating device whereby excess heat is removed from said coolant.

37. A heat removal apparatus according to claim 29 further comprising a heat exchanging device attached to said coolant circulating device whereby excess heat is removed from said coolant.

38. A heat removal apparatus according to claim 29 further comprising a coolant filter attached to said coolant circulating device whereby impurities may be removed from said coolant.

39. A heat removal apparatus according to claim 29 further comprising a coolant reservoir filter attached to said coolant circulating device whereby coolant can be stored for later use in said heat sink.

40. A heat removal apparatus according to claim 29 wherein said heat sink comprises a heat-conducting material selected from the group consisting of silicon.

41. A heat removal apparatus according to claim 29 wherein said micro-channels individually comprise dimensions less than one-sixteenth of an inch in width and height and proportional to said heat generating surface in length.
Electronic Device with Generic Heat Sink and Dish Heat Pipe

42. A heat removal apparatus for use with heat generating electronics, said heat removal apparatus comprising:
(a) a flat-shaped heat pipe, said flat-shaped heat pipe comprising: (1) a circular first surface, (2) a circular second surface substantially parallel to said circular first surface, (3) porous wicks attached to the inner surfaces of said first and second surfaces, and (4) a plurality of wicks running between said first surface and said second surface, said wicks running from the center of said heat pipe to the edge of said heat pipe and positioned so as to create substantially similar divergent vapor channels in said heat pipe;
(b) at least one heat-generating electronic component, said heat-generating electronic component having (1) a top surface, (2) a bottom surface opposite said top surface, and (3) conductive leads extending from said electronic component in a direction substantially opposite said top surface, said top surface of each said electronic component in contact with said first surface of said heat pipe; and
(c) a multi-layer microchannel heat sink, said heat sink comprising: (1) a plurality of layers, each of said layers comprising a plurality of micro-channels, each of said layers in thermal contact with at least one other said layer; and (2) a device for circulating a coolant through said plurality of layers such that said coolant flows through at least two of said plurality of layers in different directions, said heat sink placed in thermal contact with said second surface of said heat pipe.

43. A heat removal apparatus according to claim 42 additionally comprising an evaporation section on one of said surfaces of said heat pipe.

44. A heat removal apparatus according to claim 42 wherein said walls of said heat pipe comprise a conductive metal.

45. A heat removal apparatus according to claim 44 wherein said conductive metal comprises a plate of a metal selected from the group consisting of copper and aluminum.

46. A heat removal apparatus according to claim 42 wherein said wicks are comprised of a porous material.

47. A heat removal apparatus according to claim 46 wherein said porous material is adapted to act as a return mechanism for condensate generated by said heat pipe.

48. A heat removal apparatus according to claim 46 wherein said porous material comprises sintered copper powder.

49. A heat removal apparatus according to claim 42 further comprising a cooling device attached to said coolant circulating device whereby excess heat is removed from said coolant.

50. A heat removal apparatus according to claim 42 further comprising a heat exchanging device attached to said coolant circulating device whereby excess heat is removed from said coolant.

51. A heat removal apparatus according to claim 42 further comprising a coolant filter attached to said coolant circulating device whereby impurities may be removed from said coolant.

52. A heat removal apparatus according to claim 42 further comprising a coolant reservoir filter attached to said coolant circulating device whereby coolant can be stored for later use in said heat sink.

53. A heat removal apparatus according to claim 42 wherein said heat sink comprises a heat-conducting material selected from the group consisting of silicon.

54. A heat removal apparatus according to claim 42 wherein said micro-channels individually comprise dimensions less than one-sixteenth of an inch in width and height and proportional to said heat generating surface in length.
Plate Heat Pipe Method

55. A method for removing heat from electronic circuitry, said method comprising the step of placing a flat plate heat pipe in contact with the exterior surface of said electronic circuitry opposite the direction of the conductive leads of said circuitry, said heat pipe comprising: (1) a first surface, (2) a second surface substantially parallel to said first surface, (3) substantially parallel side walls connecting said first surface and said second surface on two sides, (4) porous wicks attached to the inner surfaces of said side walls and said first and second surfaces, and (5) a plurality of substantially parallel wicks running between said first surface and said second surface, said wicks positioned so as to create vapor channels in said heat pipe.
Disk Heat Pipe Method

56. A method for removing heat from electronic circuitry, said method comprising the step of placing a flat plate heat pipe in contact with the exterior surface of said electronic circuitry opposite the direction of the conductive leads of said circuitry, said heat pipe comprising: (1) a circular top surface, (2) a circular bottom surface substantially parallel to said circular top surface, (3) porous wicks attached to the inner surfaces of said top and bottom surfaces, and (4) a plurality of wicks running between said top surface and said bottom surface, said wicks running from the center of said heat pipe to the edge of said heat pipe and positioned so as to create substantially similar divergent vapor channels in said heat pipe.
Heat Sink Method

57. A method for removing heat from electronic circuitry, said method comprising the step of placing a multi-layer microchannel heat sink in contact with the exterior surface of said electronic circuitry opposite the direction of the conductive leads of said circuitry, said multi-layer microchannel heat sink comprising: a multi-layer microchannel heat sink, said heat sink comprising: (1) a plurality of layers, each of said layers comprising a plurality of micro-channels, each of said layers in thermal contact with at least one other said layer; and (2) a device for circulating a coolant through said plurality of layers such that said coolant flows through at least two of said plurality of layers in different directions.
Combination Method with Rectangular Plate

58. A method for removing heat from electronic circuitry, said method comprising the steps of:
(a) placing a flat plate heat pipe in contact with the exterior surface of said electronic circuitry opposite the direction of the conductive leads of said circuitry, said heat pipe comprising: (1) a first surface, (2) a second surface substantially parallel to said first surface, (3) substantially parallel side walls connecting said first surface and said second surface on two sides, (4) porous wicks attached to the inner surfaces of said side walls and said first and second surfaces, and (5) a plurality of substantially parallel wicks running between said first surface and said second surface, said wicks positioned so as to create vapor channels in said heat pipe; and
(b) placing a multi-layer microchannel heat sink in contact with the surface of said heat sink opposite said circuitry, said multi-layer microchannel heat sink comprising: a multi-layer microchannel heat sink, said heat sink comprising: (1) a plurality of layers, each of said layers comprising a plurality of micro-channels, each of said layers in thermal contact with at least one other said layer; and (2) a device for circulating a coolant through said plurality of layers such that said coolant flows through at least two of said plurality of layers in different directions.
Combination Method with Disk Pipe

59. A method for removing heat from electronic circuitry, said method comprising the steps of:
(a) placing a flat-shaped heat pipe in contact with the exterior surface of said electronic circuitry opposite the direction of the conductive leads of said circuitry, said heat pipe comprising: (1) a circular top surface, (2) a circular bottom surface substantially parallel to said circular top surface, (3) porous wicks attached to the inner surfaces of said top and bottom surfaces, and (4) a plurality of wicks running between said top surface and said bottom surface, said wicks running from the center of said heat pipe to the edge of said heat pipe and positioned so as to create substantially similar divergent vapor channels in said heat pipe; and
(b) placing a multi-layer microchannel heat sink in contact with the surface of said heat sink opposite said circuitry, said multi-layer microchannel heat sink comprising: a multi-layer microchannel heat sink, said heat sink comprising: (1) a plurality of layers, each of said layers comprising a plurality of micro-channels, each of said layers in thermal contact with at least one other said layer; and (2) a device for circulating a coolant through said plurality of layers such that said coolant flows through at least two of said plurality of layers in different directions
